(19) United States
(12) Patent Application Publication
(10) Pub. No.: US 2015/0236278 A1
(43) Pub. Date: Aug. 20, 2015

(54) BLUE LUMINESCENT COMPOUNDS

(71) Applicant: E.I. DU PONT DE NEMOURS AND COMPANY, Wilmington, DE (US)

(72) Inventors: Lois Bryman, West Chester, PA (US); Kerwin D. Dobbs, Wilmington, DE (US); Jerald Feldman, Wilmington, DE (US); Troy C. Gehret, Wilmington, DE (US); Stephan James McLain, Wilmington, DE (US); Charles D. McLaren, Landenberg, PA (US); Giang Dong Vo, Wilmington, DE (US); Ying Wang, West Chester, PA (US)

(21) Appl. No.: 14/428,494

(22) PCT Filed: Nov. 25, 2013
(86) PCT No.: PCT/US2013/071608

§ 371 Date: Mar. 16, 2015

Related U.S. Application Data
(60) Provisional application No. 61/731,110, filed on Nov. 29, 2012.

(51) Int. Cl. H01L 51/00; C09K 11/06; C07F 15/00

(52) U.S. Cl. CPC H01L 51/0085; C07F 15/0033; C09K 11/06; C09K 2211/185; H01L 51/5012

(57) ABSTRACT

There is provided a compound having Formula II

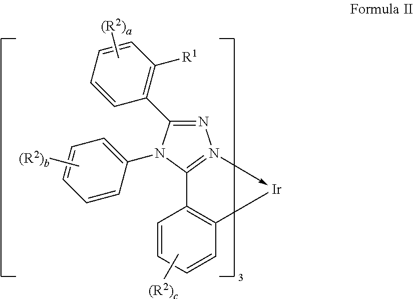

In Formula II: R¹ can be alkyl having 1-6 carbons, silyl having 3-6 carbons, or a deuterated analog thereof; R² can be alkyl, silyl, aryl, or a deuterated analog thereof; a and c are the same or different and are an integer from 0-4; and b is an integer from 0-5.

### RELATED APPLICATION DATA

This application claims priority under 35 U.S.C. §119(e) from U.S. Provisional Application No. 61/731,110 filed on Nov. 29, 2012, which is incorporated by reference herein in its entirety.

### BACKGROUND INFORMATION

1. Field of the Disclosure

This disclosure relates in general to blue luminescent compounds and their use in electronic devices.

2. Description of the Related Art

Organic electronic devices that emit light, such as light-emitting diodes that make up displays, are present in many different kinds of electronic equipment. In all such devices, an organic active layer is sandwiched between two electrical contact layers. At least one of the electrical contact layers is light-transmitting so that light can pass through the electrical contact layer. The organic active layer emits light through the light-transmitting electrical contact layer upon application of electricity across the electrical contact layers.

It is well known to use organic electroluminescent compounds as the active component in light-emitting diodes. Simple organic molecules, such as anthracene, thiadiazole derivatives, and coumarin derivatives are known to show electroluminescence. Metal complexes, particularly iridium and platinum complexes are also known to show electroluminescence. In some cases these small molecule compounds are present as a dopant in a host material to improve processing and/or electronic properties.

There is a continuing need for new luminescent compounds.

### SUMMARY

There is provided a compound having Formula I

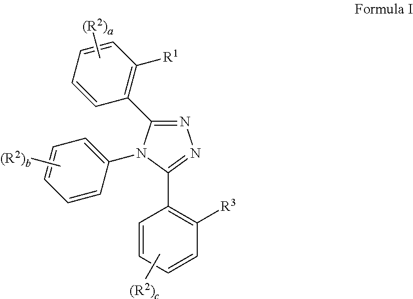

wherein:
R¹ is selected from the group consisting of alkyl having 1-6 carbons, silyl having 3-6 carbons, and deuterated analogs thereof;
R² is the same or different at each occurrence and is selected from the group consisting of alkyl, silyl, aryl, and deuterated analogs thereof;
R³ is H or D;
a and c are the same or different and are an integer from 0-5; and b is an integer from 0-5.

There is also provided a material having Formula II

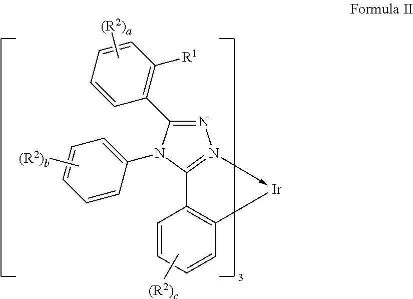

wherein:
R¹ is selected from the group consisting of alkyl having 1-6 carbons, silyl having 3-6 carbons, and deuterated analogs thereof;
R² is the same or different at each occurrence and is selected from the group consisting of alkyl, silyl, aryl, and deuterated analogs thereof;
a and c are the same or different and are an integer from 0-5; and
b is an integer from 0-5.

There is also provided an organic electronic device comprising a first electrical contact, a second electrical contact and a photoactive layer there between, the photoactive layer comprising the material having Formula II.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes an illustration of an organic light-emitting device.

FIG. 2 includes another illustration of an organic light-emitting device.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by the Material Having Formula I or Formula II, Synthesis, Devices, and finally Examples.

### 1. DEFINITIONS AND CLARIFICATION OF TERMS

Before addressing details of embodiments described below, some terms are defined or clarified.

The term “alkyl” is intended to mean a group derived from an aliphatic hydrocarbon and includes a linear, a branched, or a cyclic group. In some embodiments, an alkyl has from 1-20 carbon atoms.

The term “anti-quenching” when referring to a layer or material, refers to such layer or material which prevents quenching of blue luminance by the electron transport layer, either via an energy transfer or an electron transfer process.

The term “aromatic compound” is intended to mean an organic compound comprising at least one unsaturated cyclic group having delocalized pi electrons.

The term “aryl” is intended to mean a group derived from an aromatic hydrocarbon having one point of attachment. The term includes groups which have a single ring and those which have multiple rings which can be joined by a single bond or fused together. The term is intended to include both hydrocarbon aryls, having only carbon in the ring structure, and heteroaryls. The term “alkylaryl” is intended to mean an aryl group having one or more alkyl substituents. In some embodiments, a hydrocarbon aryl has 6-60 ring carbons. In some embodiments, a heteroaryl has 3-60 ring carbons.

The term “charge transport,” when referring to a layer, material, member, or structure is intended to mean such layer, material, member, or structure facilitates migration of such charge through the thickness of such layer, material, member, or structure with relative efficiency and small loss of charge. Hole transport materials facilitate positive charge; electron transport materials facilitate negative charge. Although light-emitting materials may also have some charge transport properties, the term “charge transport layer, material, member, or structure” is not intended to include a layer, material, member, or structure whose primary function is light emission.

The term “deuterated” is intended to mean that at least one hydrogen has been replaced by deuterium, abbreviated herein as “D”. The term “deuterated analog” refers to a structural analog of a compound or group in which one or more available hydrogens have been replaced with deuterium. In a deuterated compound or deuterated analog, the deuterium is present in at least 100 times the natural abundance level.

The term “dopant” is intended to mean a material, within a layer including a host material, that changes the electronic characteristic(s) or the targeted wavelength(s) of radiation emission, reception, or filtering of the layer compared to the electronic characteristic(s) or the wavelength(s) of radiation emission, reception, or filtering of the layer in the absence of such material.

The prefix “hetero” indicates that one or more carbon atoms have been replaced with a different atom. In some embodiments, the different atom is N, O, or S.

The term “host material” is intended to mean a material, usually in the form of a layer, to which a dopant may be added. The host material may or may not have electronic characteristic(s) or the ability to emit, receive, or filter radiation.

The terms “luminescent material” and “emitter” are intended to mean a material that emits light when activated by an applied voltage (such as in a light-emitting diode or light-emitting electrochemical cell).

The term “layer” is used interchangeably with the term “film” and refers to a coating covering a desired area. The term is not limited by size. The area can be as large as an entire device or as small as a specific functional area such as the actual visual display, or as small as a single sub-pixel. Layers and films can be formed by any conventional deposition technique, including vapor deposition, liquid deposition (continuous and discontinuous techniques), and thermal transfer. Continuous deposition techniques, include but are not limited to, spin coating, gravure coating, curtain coating, dip coating, slot-die coating, spray coating, and continuous nozzle coating or printing. Discontinuous deposition techniques include, but are not limited to, ink jet printing, gravure printing, and screen printing.

The term “organic electronic device” or sometimes just “electronic device” is intended to mean a device including one or more organic semiconductor layers or materials.

The term “photoactive” refers to a material or layer that emits light when activated by an applied voltage (such as in a light emitting diode or chemical cell) or responds to radiant energy and generates a signal with or without an applied bias voltage (such as in a photodetector or a photovoltaic cell).

All groups may be unsubstituted or substituted. The substituent groups are discussed below.

In this specification, unless explicitly stated otherwise or indicated to the contrary by the context of usage, where an embodiment of the subject matter hereof is stated or described as comprising, including, containing, having, being composed of or being constituted by or of certain features or elements, one or more features or elements in addition to those explicitly stated or described may be present in the embodiment. An alternative embodiment of the disclosed subject matter hereof, is described as consisting essentially of certain features or elements, in which embodiment features or elements that would materially alter the principle of operation or the distinguishing characteristics of the embodiment are not present therein. A further alternative embodiment of the described subject matter hereof is described as consisting of certain features or elements, in which embodiment, or in insubstantial variations thereof, only the features or elements specifically stated or described are present.

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic cell, and semiconductive member arts.

### 2. COMPOUNDS HAVING FORMULA I OR FORMULA II

There is provided herein a new compound having Formula I

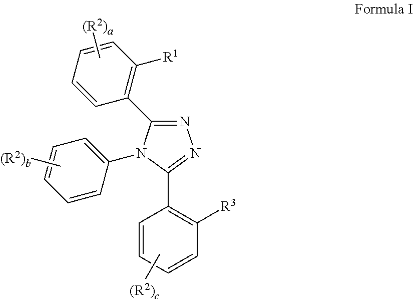

wherein:
R¹ is selected from the group consisting of alkyl having 1-6 carbons, silyl having 3-6 carbons, and deuterated analogs thereof;
R² is the same or different at each occurrence and is selected from the group consisting of alkyl, silyl, aryl, and deuterated analogs thereof;
R³ is H or D;
a and c are the same or different and are an integer from 0-5; and
b is an integer from 0-5.

The new compounds having Formula I can be used as ligands to form metal complexes having Formula II

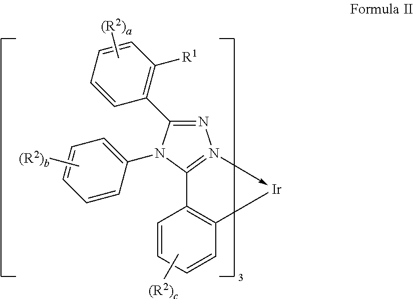

wherein:
R¹ is selected from the group consisting of alkyl having 1-6 carbons, silyl having 3-6 carbons, and deuterated analogs thereof;
R² is the same or different at each occurrence and is selected from the group consisting of alkyl, silyl, aryl, and deuterated analogs thereof;
a and c are the same or different and are an integer from 0-5; and
b is an integer from 0-5.

In some embodiments, the compounds having Formula II are useful as emissive materials. The compound having Formula II are capable of blue electroluminescence. The compounds can be used alone or as a dopant in a host material.

The compounds having Formula II are soluble in many commonly used organic solvents. Solutions of these compounds can be used for liquid deposition using techniques such as discussed above. Surprisingly, it has been found that the compounds having an ortho alkyl group shown as R¹ in Formula II have an unexpected shift in emission toward blue. In some embodiments, the compounds have an electroluminescent (“EL”) peak less than 500 nm. In some embodiments, the compounds have an EL peak in the range of 445-490 nm. In some embodiments, the compounds used in devices result in color coordinates of x<0.25 and y<0.5, according to the 1931 C.I.E. convention (Commission Internationale de L'Eclairage, 1931).

Also surprisingly, such compounds provide other advantages in electronic devices. In some embodiments, devices made with compounds having Formula II have improved efficiencies and lifetimes. This is advantageous for reducing energy consumption in all types of devices, and particularly for lighting applications. Higher efficiency also improves device lifetime at constant luminance.

Specific embodiments of the present invention include, but are not limited to, the following.

### Embodiment 1

The compound of Formula I or Formula II, wherein the compound is deuterated.

### Embodiment 2

The compound of Formula I or Formula II, wherein the compound is at least 10% deuterated. By “% deuterated” or “% deuteration” is meant the ratio of deuterons to the total of hydrogens plus deuterons, expressed as a percentage. The deuteriums may be on the same or different groups.

### Embodiment 3

The compound of Formula I or Formula II, wherein the compound is at least 25% deuterated.

### Embodiment 4

The compound of Formula I or Formula II, wherein the compound is at least 50% deuterated.

### Embodiment 5

The compound of Formula I or Formula II, wherein the compound is at least 75% deuterated.

### Embodiment 6

The compound of Formula I or Formula II, wherein the compound is at least 90% deuterated.

### Embodiment 7

The compound of Formula I or Formula II, wherein R¹ is an unsubstituted alkyl or unsubstituted deuterated alkyl having 1-6 carbons.

### Embodiment 8

The compound of Formula I or Formula II, wherein R¹ is an unsubstituted alkyl or unsubstituted deuterated alkyl having 1-3 carbons.

### Embodiment 9

The compound of Formula I or Formula II, wherein R¹ is a silyl or deuterated silyl having 3-6 carbons.

### Embodiment 10

The compound of Formula I or Formula II, wherein a=1.

### Embodiment 11

The compound of Formula I or Formula II, wherein a=2.

### Embodiment 12

The compound of Formula I or Formula II, wherein a>1 and R² is meta to R¹.

### Embodiment 13

The compound of Formula I or Formula II, wherein a>0 and R² is an alkyl or deuterated alkyl having 1-6 carbons.

### Embodiment 14

The compound of Formula I or Formula II, wherein a>0 and R² is a silyl or deuterated silyl having 3-6 carbons.

### Embodiment 15

The compound of Formula I or Formula II, wherein a>0 and R² is a hydrocarbon aryl or deuterated hydrocarbon aryl having 6-12 ring carbons.

### Embodiment 16

The compound of Formula I or Formula II, wherein a>0 and R² is an alkylaryl or deuterated alkylaryl having 6-20 carbons.

### Embodiment 17

The compound of Formula I or Formula II, wherein b=1.

### Embodiment 18

The compound of Formula I or Formula II, wherein b=2.

### Embodiment 19

The compound of Formula I or Formula II, wherein b>0 and R² is an alkyl or deuterated alkyl having 1-6 carbons.

### Embodiment 20

The compound of Formula I or Formula II, wherein b>0 and R² is a silyl or deuterated silyl having 3-6 carbons.

### Embodiment 21

The compound of Formula I or Formula II, wherein b>0 and R² is a hydrocarbon aryl or deuterated hydrocarbon aryl having 6-12 ring carbons.

### Embodiment 22

The compound of Formula I or Formula II, wherein b>0 and R² is an alkylaryl or deuterated alkylaryl having 6-20 carbons.

### Embodiment 23

The compound of Formula I or Formula II, wherein c=1.

### Embodiment 24

The compound of Formula I or Formula II, wherein c=2.

### Embodiment 25

The compound of Formula I or Formula II, wherein c>0 and R² is an alkyl or deuterated alkyl having 1-6 carbons.

### Embodiment 26

The compound of Formula I or Formula II, wherein c>0 and R² is a silyl or deuterated silyl having 3-6 carbons.

### Embodiment 27

The compound of Formula I or Formula II, wherein c>0 and R² is a hydrocarbon aryl or deuterated hydrocarbon aryl having 6-12 ring carbons.

### Embodiment 28

The compound of Formula I or Formula II, wherein c>0 and R² is an alkylaryl or deuterated alkylaryl having 6-20 carbons.

### Embodiment 29

The compound of Formula I or Formula II, wherein a=0

### Embodiment 30

The compound of Formula I or Formula II, wherein b=0.

### Embodiment 31

The compound of Formula I or Formula II, wherein c=0.

Any of the above embodiments can be combined with one or more of the other embodiments, so long as they are not mutually exclusive. For example, the embodiment in which R¹ is a secondary alkyl or deuterated secondary alkyl having 3-20 carbons can be combined with the embodiment in which R² is selected from the group consisting of methyl, propyl, butyl, and deuterated analogs thereof. The same is true for the other non-mutually-exclusive embodiments discussed above. The skilled person would understand which embodiments were mutually exclusive and would thus readily be able to determine the combinations of embodiments that are contemplated by the present application.

Examples of compounds having Formula I include, but are not limited to, the compounds shown below.

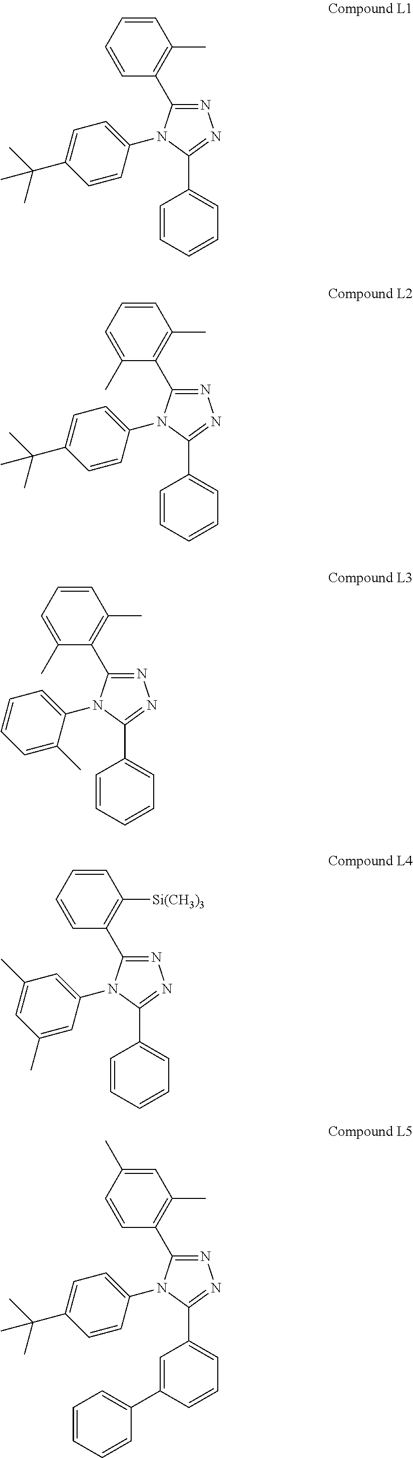

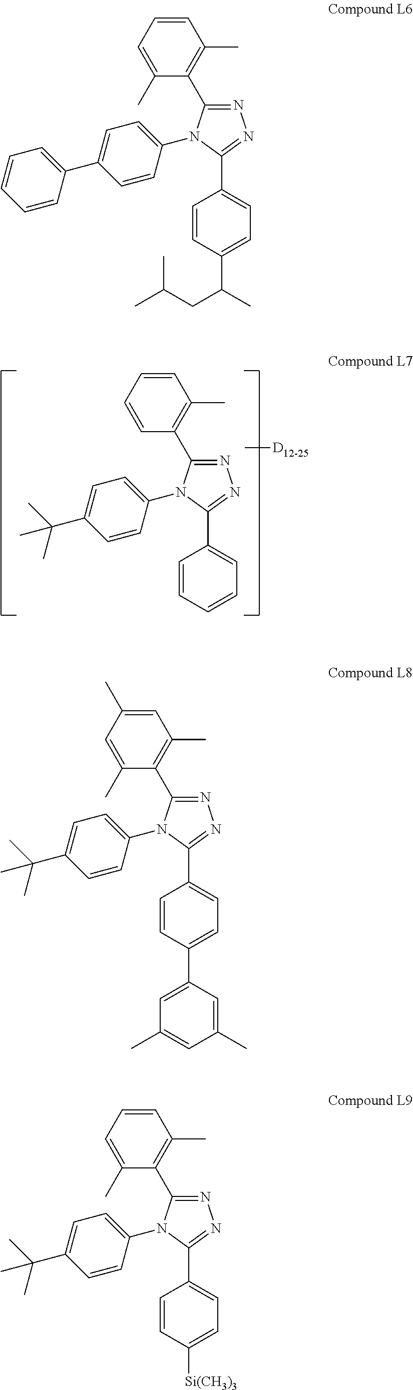

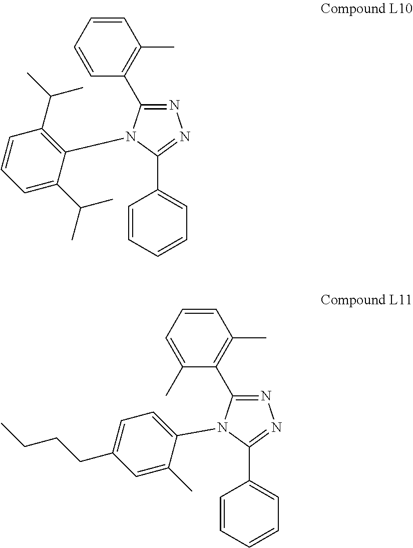 [SMILES: Cc1ccccc1-c1nnc(-c2ccccc2)n1-c1c(C(C)C)cccc1C(C)C ; CCCCc1ccc(-n2c(-c3ccccc3)nnc2-c2c(C)cccc2C)c(C)c1]

Examples of compounds having Formula II include, but are not limited to, the compounds shown below.

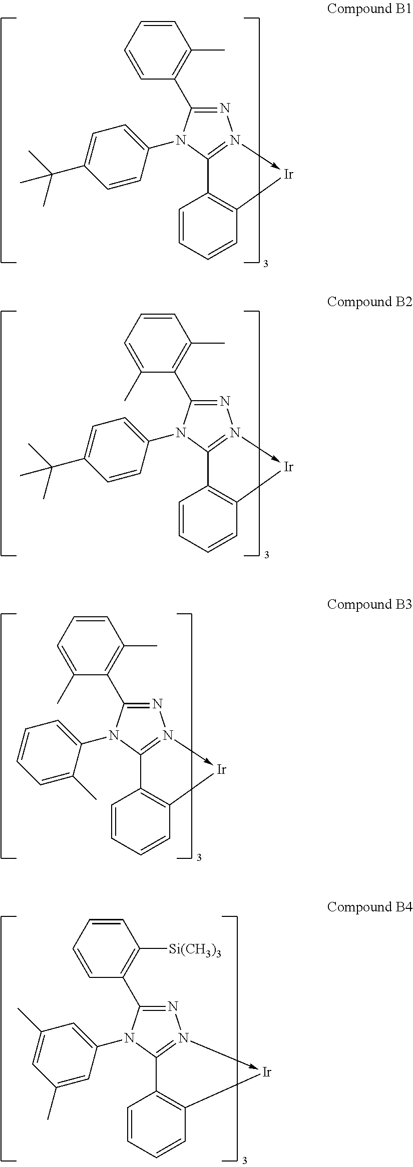

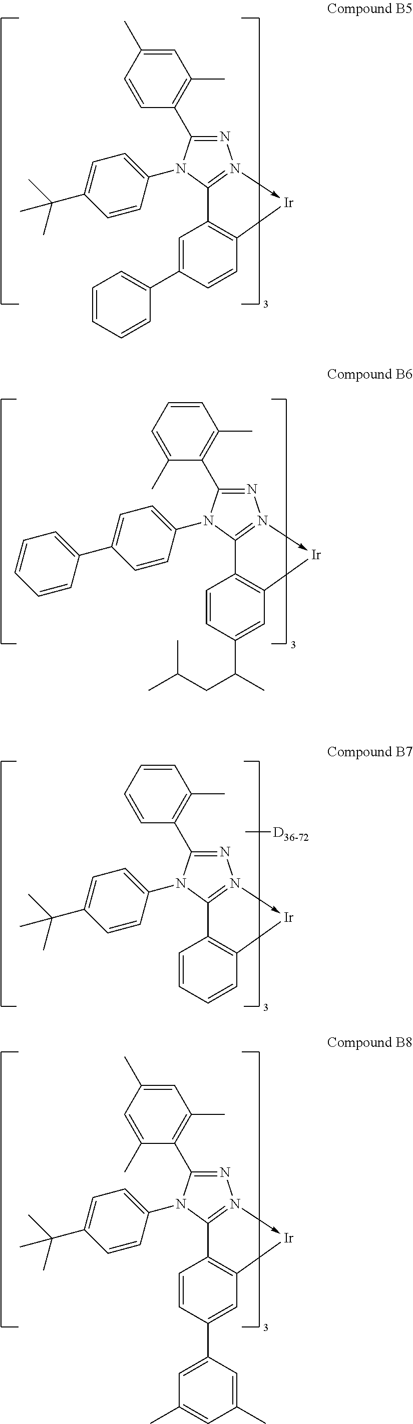

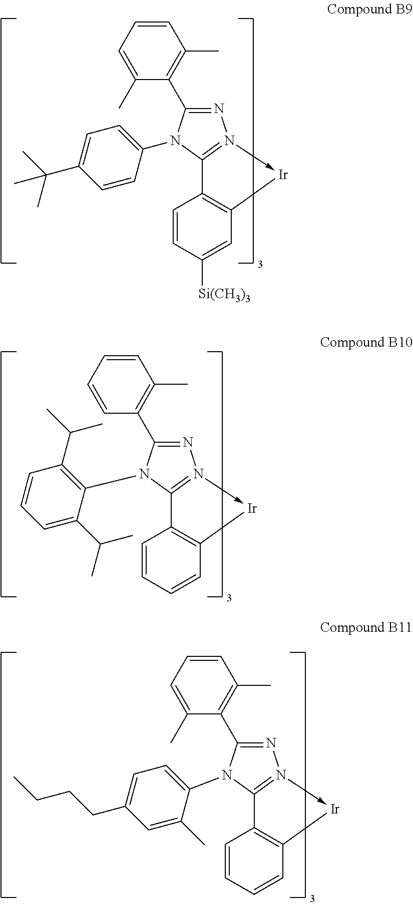

### 3. SYNTHESIS

The compounds having Formula I described herein can be synthesized by a variety of procedures that have precedent in the literature. The exact procedure chosen will depend on a variety of factors, including availability of starting materials and reaction yield.

In one method a diaryl 1,3,4-oxadiazole is prepared from a carboxylic acid and an acyl hydrazide (Dickson, H. D.; Li, C. Tet. Lett. 2009, 50, 6435). The 1,3,4-oxadiazole is then allowed to react with an aniline in the presence of aluminum chloride to afford the desired 4H-1,2,4-triazole (Chiriac, C. I. et al., Rev. Roum. Chim. 2010, 55, 175). An example of this method is shown below, where HATU=2-(7-Aza-1H-Benzotriazole-1-yl)-1,1,3,3-tetramethyluronium hexafluorophosphate, DEA=disopropylethylamine, Burgess Reagent=methyl N-(triethylammoniumsulfonyl)carbamate, THF=tetrahydrofuran, and NMP=1-methyl-2-pyrollidinone).

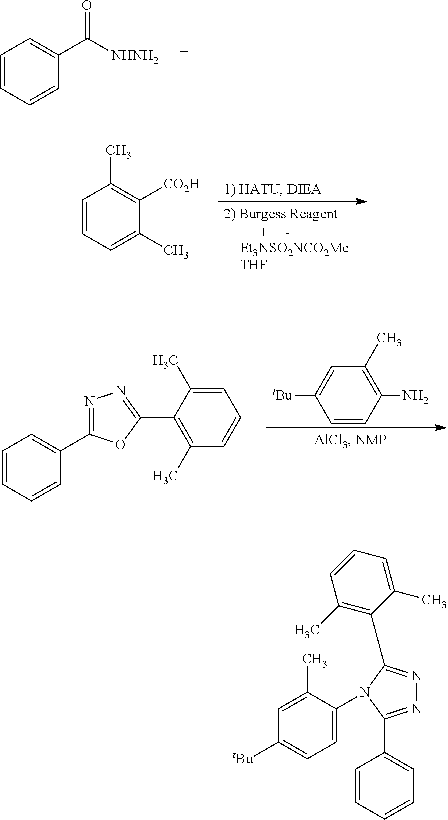 [SMILES: NNC(=O)c1ccccc1 ; Cc1cccc(C)c1C(=O)O ; Cc1cccc(C)c1-c1nnc(-c2ccccc2)o1 ; Cc1cc(C(C)(C)C)ccc1N ; Cc1cc(C(C)(C)C)ccc1-n1c(-c2ccccc2)nnc1-c1c(C)cccc1C]

In another method, 2-phenyl-1,3,4-oxadiazole is allowed to react with an aniline, affording a diaryl-substituted triazole (Korotikh, N. I. et al. Chemistry of Heterocyclic Compounds 2005, 41, 866). The triazole is then allowed to react with N-bromosuccinimide affording a brominated 1,2,4-triazole, which then undergoes Suzuki coupling to afford a triaryl-substituted 4H-1,2,4-triazole. An example of this method is shown below:

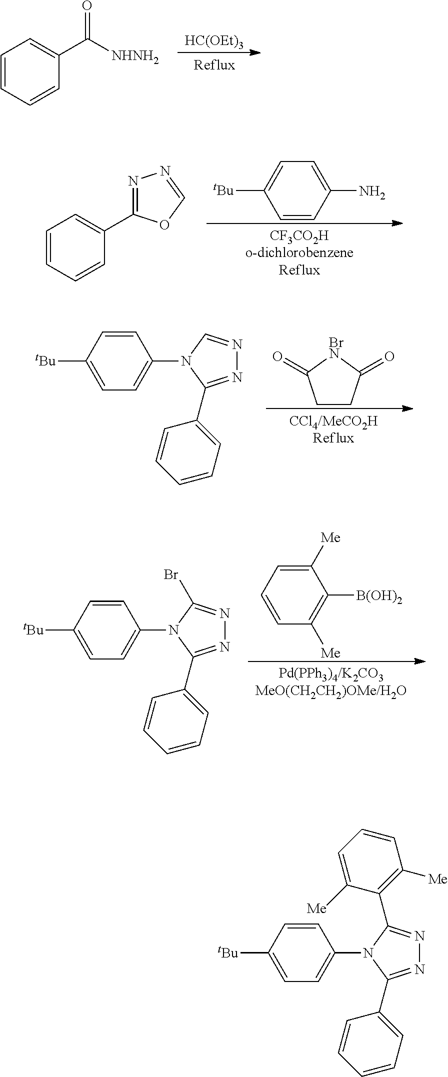

The Huisgen rearrangement reaction is yet another method that was used to prepare sterically hindered 4H-1,2,4-triazoles (Kaim, L. E.; Grimaud, L.; Patil, P. Org. Lett. 2011, 13, 1261.). The rearrangement takes advantage of the fast kinetics of an intramolecular cyclization driven by generation of N₂ to form bonds between bulky groups. The synthetic sequence is summarized below. It is modular and convergent, allowing for flexibility in tuning the substituents on the triazole core. The starting materials for the Huisgen rearrangement can be prepared from the readily available isonitrile and 5-phenyl-1H-tetrazole. In the same pot, the tetrazolyl imidoyl bromide undergoes rearrangement to from 3-bromo-1,2,4-triazole. The last step of the ligand synthesis is the Suzuki-Miyaura cross-coupling reaction.

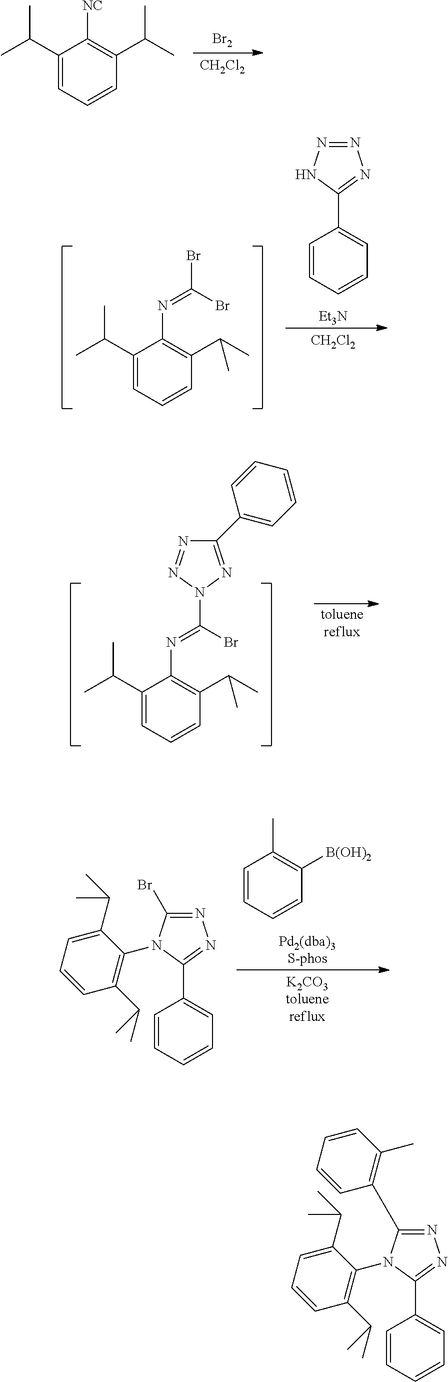

The compounds having Formula II were prepared by the reaction of commercially available Ir(acetylacetonate)₃ with excess ligand at elevated temperatures. This reaction typically results in cyclometallation of three equivalents of ligand onto iridium and formation of three equivalents of acetylacetone. The IrL₃ product, wherein L is the cyclometallated ligand, can be isolated and purified by chromatography and/or recrystallization.

### 4. DEVICES

Organic electronic devices that may benefit from having one or more layers comprising the compounds having Formula II described herein include, but are not limited to, (1) devices that convert electrical energy into radiation (e.g., a light-emitting diode, light emitting diode display, lighting device, luminaire, or diode laser), (2) devices that detect signals through electronics processes (e.g., photodetectors, photoconductive cells, photoresistors, photoswitches, phototransistors, phototubes, IR detectors, biosensors), (3) devices that convert radiation into electrical energy, (e.g., a photovoltaic device or solar cell), and (4) devices that include one or more electronic components that include one or more organic semi-conductor layers (e.g., a transistor or diode).

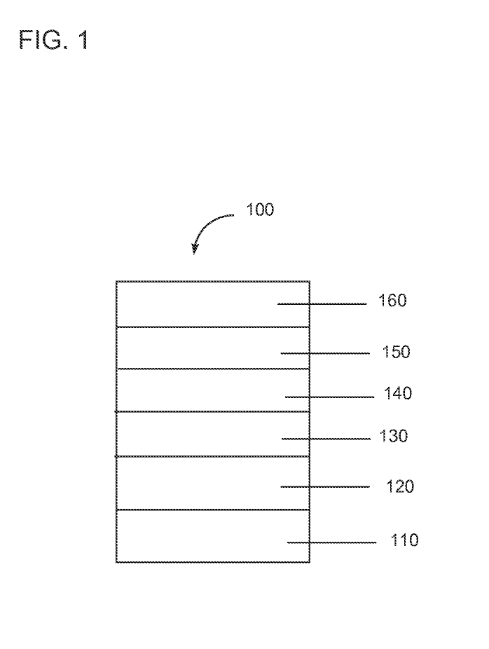

One illustration of an organic electronic device structure is shown in FIG. 1. The device 100 has a first electrical contact layer, an anode layer 110 and a second electrical contact layer, a cathode layer 160, and a photoactive layer 140 between them. Adjacent to the anode is a hole injection layer 120. Adjacent to the hole injection layer is a hole transport layer 130, comprising hole transport material. Adjacent to the cathode may be an electron transport layer 150, comprising an electron transport material. As an option, devices may use one or more additional hole injection or hole transport layers (not shown) next to the anode 110 and/or one or more additional electron injection or electron transport layers (not shown) next to the cathode 160. As a further option, devices may have an anti-quenching layer (not shown) between the photoactive layer 140 and the electron transport layer 150.

Layers 120 through 150, and any additional layers between them, are individually and collectively referred to as the active layers.

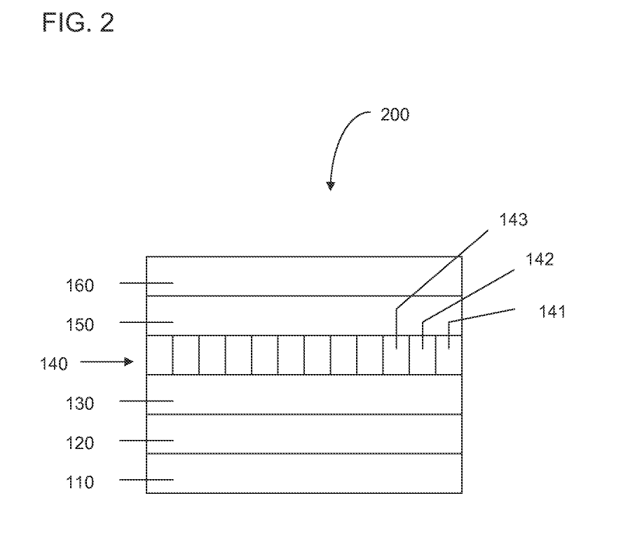

In some embodiments, the photoactive layer is pixellated, as shown in FIG. 2. In device 200, layer 140 is divided into pixel or subpixel units 141, 142, and 143 which are repeated over the layer. Each of the pixel or subpixel units represents a different color. In some embodiments, the subpixel units are for red, green, and blue. Although three subpixel units are shown in the figure, two or more than three may be used.

In one embodiment, the different layers have the following range of thicknesses: anode 110, 500-5000 Å, in one embodiment 1000-2000 Å; hole injection layer 120, 50-2000 Å, in one embodiment 200-1000 Å; hole transport layer 120, 50-2000 Å, in one embodiment 200-1000 Å; photoactive layer 130, 10-2000 Å, in one embodiment 100-1000 Å; layer 140, 50-2000 Å, in one embodiment 100-1000 Å; cathode 150, 200-10000 Å, in one embodiment 300-5000 Å. The location of the electron-hole recombination zone in the device, and thus the emission spectrum of the device, can be affected by the relative thickness of each layer. The desired ratio of layer thicknesses will depend on the exact nature of the materials used.

In some embodiments, the compounds having Formula II are useful as the emissive material in photoactive layer 140, having blue emission color. They can be used alone or as a dopant in a host material.

a. Photoactive Layer

In some embodiments, the photoactive layer comprises a host material and a compound having Formula II as a dopant. In some embodiments, a second host material may be present. In some embodiments, the photoactive layer consists essentially of a host material and a compound having Formula II as a dopant. In some embodiments, the photoactive layer consists essentially of a first host material, a second host material, and a compound having Formula II as a dopant. The weight ratio of dopant to total host material is in the range of 5:95 to 70:30; in some embodiments, 10:90 to 20:80.

In some embodiments, the host has a triplet energy level higher than that of the dopant, so that it does not quench the emission. In some embodiments, the host is selected from the group consisting of carbazoles, indolocarbazoles, triazines, aryl ketones, phenylpyridines, pyrimidines, phenanthrolines, triarylamines, deuterated analogs thereof, combinations thereof, and mixtures thereof.

In some embodiments, the photoactive layer is intended to emit white light. In some embodiments, the photoactive layer comprises a host, a compound of Formula II, and one or more additional dopants emitting different colors, so that the overall emission is white. In some embodiments, the photoactive layer consists essentially of a host, a first dopant having Formula II, and a second dopant, where the second dopant emits a different color than the first dopant. In some embodiments, the emission color of the second dopant is yellow. In some embodiments, the photoactive layer consists essentially of a host, a first dopant having Formula II, a second dopant, and a third dopant. In some embodiments, the emission color of the second dopant is red and the emission color of the third dopant is green.

Any kind of electroluminescent (“EL”) material can be used as second and third dopants. EL materials include, but are not limited to, small molecule organic fluorescent compounds, luminescent metal complexes, conjugated polymers, and mixtures thereof. Examples of fluorescent compounds include, but are not limited to, chrysenes, pyrenes, perylenes, rubrenes, coumarins, anthracenes, thiadiazoles, derivatives thereof, arylamino derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Examples of conjugated polymers include, but are not limited to poly(phenylenevinylenes), polyfluorenes, poly(spirobifluorenes), polythiophenes, poly(p-phenylenes), copolymers thereof, and mixtures thereof.

Examples of red, orange and yellow light-emitting materials include, but are not limited to, complexes of Ir having phenylquinoline or phenylisoquinoline ligands, periflanthenes, fluoranthenes, and perylenes. Red light-emitting materials have been disclosed in, for example, U.S. Pat. No. 6,875,524, and published US application 2005-0158577.

In some embodiments, the second and third dopants are cyclometallated complexes of Ir or Pt.

b. Other Device Layers

The other layers in the device can be made of any materials which are known to be useful in such layers.

The anode 110 is an electrode that is particularly efficient for injecting positive charge carriers. It can be made of, for example materials containing a metal, mixed metal, alloy, metal oxide or mixed-metal oxide, or it can be a conducting polymer, and mixtures thereof. Suitable metals include the Group 11 metals, the metals in Groups 4, 5, and 6, and the Group 8-10 transition metals. If the anode is to be light-transmitting, mixed-metal oxides of Groups 12, 13 and 14 metals, such as indium-tin-oxide, are generally used. The anode may also comprise an organic material such as polyaniline as described in “Flexible light-emitting diodes made from soluble conducting polymer,” Nature vol. 357, pp 477 479 (11 Jun. 1992). At least one of the anode and cathode should be at least partially transparent to allow the generated light to be observed.

The hole injection layer 120 comprises hole injection material and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. The hole injection layer can be formed with polymeric materials, such as polyaniline (PANI) or polyethylenedioxythiophene (PEDOT), which are often doped with protonic acids. The protonic acids can be, for example, poly(styrenesulfonic acid), poly(2-acrylamido-2-methyl-1-propanesulfonic acid), and the like.

The hole injection layer can comprise charge transfer compounds, and the like, such as copper phthalocyanine and the tetrathiafulvalene-tetracyanoquinodimethane system (TTF-TCNQ).

In some embodiments, the hole injection layer comprises at least one electrically conductive polymer and at least one fluorinated acid polymer.

In some embodiments, the hole injection layer is made from an aqueous dispersion of an electrically conducting polymer doped with a colloid-forming polymeric acid. Such materials have been described in, for example, published U.S. patent applications US 2004/0102577, US 2004/0127637, US 2005/0205860, and published PCT application WO 2009/018009.

Examples of hole transport materials for layer 130 have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules are: N,N′-diphenyl-N,N′-bis(3-methylphenyl)-[1,1′-biphenyl]-4,4′-diamine (TPD), 1,1-bis[(di-4-tolylamino)phenyl]cyclohexane (TAPC), N,N′-bis(4-methylphenyl)-N,N′-bis(4-ethylphenyl)-[1,1′-(3,3′-dimethyl)biphenyl]-4,4′-diamine (ETPD), tetrakis-(3-methylphenyl)-N,N,N′,N′-2,5-phenylenediamine (PDA), a-phenyl-4-N,N-diphenylaminostyrene (TPS), p-(diethylamino)benzaldehyde diphenylhydrazone (DEH), triphenylamine (TPA), bis[4-(N,N-diethylamino)-2-methylphenyl](4-methylphenyl)methane (MPMP), 1-phenyl-3[p-(diethylamino)styryl]-5-[p-(diethylamino)phenyl]pyrazoline (PPR or DEASP), 1,2-trans-bis(9H-carbazol-9-yl)cyclobutane (DCZB), N,N,N′,N′-tetrakis(4-methylphenyl)-(1,1′-biphenyl)-4,4′-diamine (TTB), N,N′-bis(naphthalen-1-yl)-N,N′-bis-(phenyl)benzidine (—NPB), and porphyrinic compounds, such as copper phthalocyanine. In some embodiments, the hole transport layer comprises a hole transport polymer. In some embodiments, the hole transport polymer is a distyrylaryl compound. In some embodiments, the aryl group has two or more fused aromatic rings. In some embodiments, the aryl group is an acene. The term “acene” as used herein refers to a hydrocarbon parent component that contains two or more ortho-fused benzene rings in a straight linear arrangement. Other commonly used hole transporting polymers are polyvinylcarbazole, (phenylmethyl)-polysilane, and polyaniline. It is also possible to obtain hole transporting polymers by doping hole transporting molecules such as those mentioned above into polymers such as polystyrene and polycarbonate. In some cases, triarylamine polymers are used, especially triarylamine-fluorene copolymers. In some cases, the polymers and copolymers are crosslinkable.

In some embodiments, the hole transport layer further comprises a p-dopant. In some embodiments, the hole transport layer is doped with a p-dopant. Examples of p-dopants include, but are not limited to, tetrafluorotetracyanoquinodimethane (F4-TCNQ) and perylene-3,4,9,10-tetracarboxylic-3,4,9,10-dianhydride (PTCDA).

Examples of electron transport materials which can be used for layer 150 include, but are not limited to, metal chelated oxinoid compounds, including metal quinolate derivatives such as tris(8-hydroxyquinolato)aluminum (AlQ), bis(2-methyl-8-quinolinolato)(p-phenylphenolato)aluminum (BAIq), tetrakis-(8-hydroxyquinolato)hafnium (HfQ) and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); and mixtures thereof. In some embodiments, the electron transport layer further comprises an n-dopant. N-dopant materials are well known. The n-dopants include, but are not limited to, Group 1 and 2 metals; Group 1 and 2 metal salts, such as LiF, CsF, and Cs₂CO₃; Group 1 and 2 metal organic compounds, such as Li quinolate; and molecular n-dopants, such as leuco dyes, metal complexes, such as W₂(hpp)₄ where hpp=1,3,4,6,7,8-hexahydro-2H-pyrimido-[1,2-a]-pyrimidine and cobaltocene, tetrathianaphthacene, bis(ethylenedithio)tetrathiafulvalene, heterocyclic radicals or diradicals, and the dimers, oligomers, polymers, dispiro compounds and polycycles of heterocyclic radical or diradicals.

An anti-quenching layer may be present between the photoactive layer and the electron transport layer to prevent quenching of blue luminance by the electron transport layer. To prevent energy transfer quenching, the triplet energy of the anti-quenching material has to be higher than the triplet energy of the blue emitter. To prevent electron transfer quenching, the LUMO level of the anti-quenching material has to be shallow enough (with respect to the vacuum level) such that electron transfer between the emitter exciton and the anti-quenching material is endothermic. Furthermore, the HOMO level of the anti-quenching material has to be deep enough (with respect to the vacuum level) such that electron transfer between the emitter exciton and the anti-quenching material is endothermic. In general, anti-quenching material is a large band-gap material with high triplet energy.

Examples of materials for the anti-quenching layer include, but are not limited to, triphenylene, triphenylene derivatives, carbazole, carbazole derivatives, and deuterated analogs thereof. Some specific materials include those shown below.

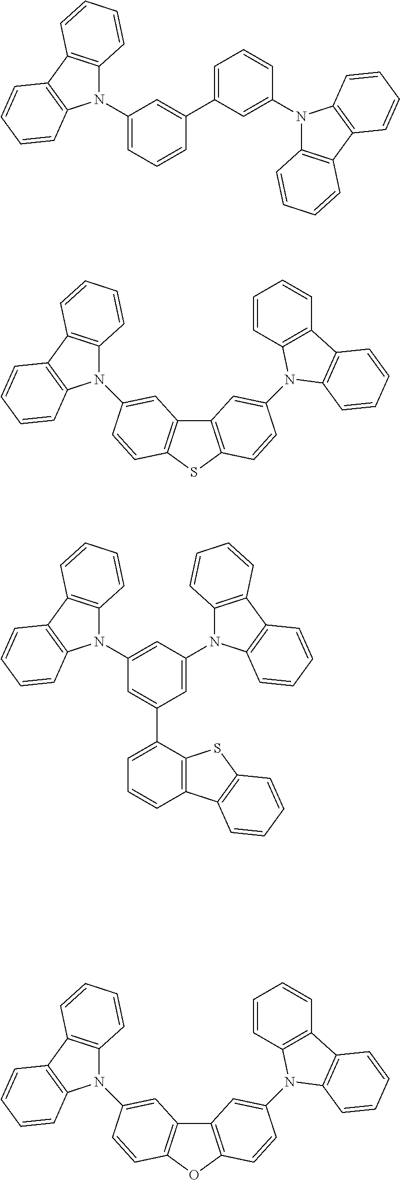 [SMILES: c1cc(-c2cccc(-n3c4ccccc4c4ccccc43)c2)cc(-n2c3ccccc3c3ccccc32)c1 ; c1ccc2c(c1)c1ccccc1n2-c1ccc2sc3ccc(-n4c5ccccc5c5ccccc54)cc3c2c1 ; c1ccc2c(c1)sc1c(-c3cc(-n4c5ccccc5c5ccccc54)cc(-n4c5ccccc5c5ccccc54)c3)cccc12 ; c1ccc2c(c1)c1ccccc1n2-c1ccc2oc3ccc(-n4c5ccccc5c5ccccc54)cc3c2c1]

The cathode 160, is an electrode that is particularly efficient for injecting electrons or negative charge carriers. The cathode can be any metal or nonmetal having a lower work function than the anode. Materials for the cathode can be selected from alkali metals of Group 1 (e.g., Li, Cs), the Group 2 (alkaline earth) metals, the Group 12 metals, including the rare earth elements and lanthanides, and the actinides. Materials such as aluminum, indium, calcium, barium, samarium and magnesium, as well as combinations, can be used.

Alkali metal-containing inorganic compounds, such as LiF, CsF, Cs₂O and Li₂O, or Li-containing organometallic compounds can also be deposited between the organic layer 150 and the cathode layer 160 to lower the operating voltage. This layer, not shown, may be referred to as an electron injection layer.

It is known to have other layers in organic electronic devices. For example, there can be a layer (not shown) between the anode 110 and hole injection layer 120 to control the amount of positive charge injected and/or to provide band-gap matching of the layers, or to function as a protective layer. Layers that are known in the art can be used, such as copper phthalocyanine, silicon oxy-nitride, fluorocarbons, silanes, or an ultra-thin layer of a metal, such as Pt. Alternatively, some or all of anode layer 110, active layers 120, 130, 140, and 150, or cathode layer 160, can be surface-treated to increase charge carrier transport efficiency. The choice of materials for each of the component layers is preferably determined by balancing the positive and negative charges in the emitter layer to provide a device with high electroluminescence efficiency.

It is understood that each functional layer can be made up of more than one layer.

c. Device Fabrication

The device layers can be formed by any deposition technique, or combinations of techniques, including vapor deposition, liquid deposition, and thermal transfer.

In some embodiments, the device is fabricated by liquid deposition of the hole injection layer, the hole transport layer, and the photoactive layer, and by vapor deposition of the anode, the electron transport layer, an electron injection layer and the cathode.

The hole injection layer can be deposited from any liquid medium in which it is dissolved or dispersed and from which it will form a film. In one embodiment, the liquid medium consists essentially of one or more organic solvents. In one embodiment, the liquid medium consists essentially of water or water and an organic solvent. The hole injection material can be present in the liquid medium in an amount from 0.5 to 10 percent by weight. The hole injection layer can be applied by any continuous or discontinuous liquid deposition technique. In one embodiment, the hole injection layer is applied by spin coating. In one embodiment, the hole injection layer is applied by ink jet printing. In one embodiment, the hole injection layer is applied by continuous nozzle printing. In one embodiment, the hole injection layer is applied by slot-die coating. After liquid deposition, the liquid medium can be removed in air, in an inert atmosphere, or by vacuum, at room temperature or with heating.

The hole transport layer can be deposited from any liquid medium in which it is dissolved or dispersed and from which it will form a film. In one embodiment, the liquid medium consists essentially of one or more organic solvents. In one embodiment, the liquid medium consists essentially of water or water and an organic solvent. In one embodiment the organic solvent is an aromatic solvent. In one embodiment, the organic liquid is selected from chloroform, dichloromethane, chlorobenzene, dichlorobenzene, toluene, xylene, mesitylene, anisole, and mixtures thereof. The hole transport material can be present in the liquid medium in a concentration of 0.2 to 2 percent by weight. The hole transport layer can be applied by any continuous or discontinuous liquid deposition technique. In one embodiment, the hole transport layer is applied by spin coating. In one embodiment, the hole transport layer is applied by ink jet printing. In one embodiment, the hole transport layer is applied by continuous nozzle printing. In one embodiment, the hole transport layer is applied by slot-die coating. After liquid deposition, the liquid medium can be removed in air, in an inert atmosphere, or by vacuum, at room temperature or with heating.

The photoactive layer can be deposited from any liquid medium in which it is dissolved or dispersed and from which it will form a film. In one embodiment, the liquid medium consists essentially of one or more organic solvents. In one embodiment, the liquid medium consists essentially of water or water and an organic solvent. In one embodiment the organic solvent is an aromatic solvent. In one embodiment, the organic solvent is selected from chloroform, dichloromethane, toluene, anisole, 2-butanone, 3-pentanone, butyl acetate, acetone, xylene, mesitylene, chlorobenzene, tetrahydrofuran, diethyl ether, trifluorotoluene, and mixtures thereof. The photoactive material can be present in the liquid medium in a concentration of 0.2 to 2 percent by weight. Other weight percentages of photoactive material may be used depending upon the liquid medium. The photoactive layer can be applied by any continuous or discontinuous liquid deposition technique. In one embodiment, the photoactive layer is applied by spin coating. In one embodiment, the photoactive layer is applied by ink jet printing. In one embodiment, the photoactive layer is applied by continuous nozzle printing. In one embodiment, the photoactive layer is applied by slot-die coating. After liquid deposition, the liquid medium can be removed in air, in an inert atmosphere, or by vacuum, at room temperature or with heating.

The electron transport layer can be deposited by any vapor deposition method. In one embodiment, it is deposited by thermal evaporation under vacuum.

The electron injection layer can be deposited by any vapor deposition method. In one embodiment, it is deposited by thermal evaporation under vacuum.

The cathode can be deposited by any vapor deposition method. In one embodiment, it is deposited by thermal evaporation under vacuum.

### EXAMPLES

The concepts described herein will be further described in the following examples, which do not limit the scope of the invention described in the claims.

### Synthesis Example 1

This example illustrates the synthesis of Compound L1 and Compound B1.

The compounds were synthesized in five steps as follows:

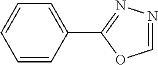 [SMILES: c1ccc(-c2nnco2)cc1]

### Step 1: Synthesis of 2-phenyl-1,3,4-oxadiazole Reference: Joseph, J.; Kim, J.-Y.; Chang, S.-B. Chem. Eur. J. 2011, 17, 8294

A 250 mL round bottom flask equipped with a nitrogen inlet, magnetic stir bar, and cooling condenser was charged with benzohydrazide (31.6 g, 232 mmol) and triethylorthoformate (100 mL). The resulting slurry was heated to reflux using a heating block set at 176° C. A clear solution resulted upon heating, and the reaction mixture was heated at reflux for 16 h before cooling to room temperature. The reaction mixture was concentrated to dryness under vacuum to afford a tan colored oil. This was redissolved in ethyl acetate and extracted 3× with 20% HCl, 1× with water, and 1× with brine. The ethyl acetate solution was dried over Na₂SO₄ and concentrated to afford 26.6 g of a gold colored oil (78%). This material was used without further purification. ¹HNMR (CD₂Cl₂) δ 8.53 (s, 1H), 8.19 (d, 2H), 7.57 (mult, 3H).

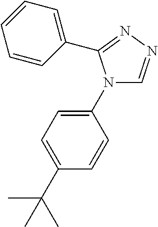 [SMILES: CC(C)(C)c1ccc(-n2cnnc2-c2ccccc2)cc1]

### Step 2: Synthesis of 4-(4-(tert-butyl)phenyl)-3-phenyl-4H-1,2,4-triazole Reference: Korotikh, N. I. et al. Chemistry of Heterocyclic Compounds 2005, 41, 866

A 500 mL round bottom flask was charged with 2-phenyl-1,3,4-oxadiazole (19.8 g, 135 mmol), 4-tBu-aniline (22.2 g, 149 mmol), 1,2-dichlorobenzene (50 mL) and trifluoroacetic acid (16.9 g, 149 mmol) respectively. The resulting mixture was heated to 181° C. using an aluminum heating block and an air cooled condenser. The reaction mixture was maintained at reflux for 20 h. Volatiles were removed by vacuum distillation to afford a clear colorless oil. The crude product was divided into smaller portions that were chromatographed separately using methylene chloride/ethyl acetate as the eluent. The final combined yield was 7.2 g of a white solid (19%). ¹HNMR (CD₂Cl₂) δ 8.21 (s, 1H), 7.39-7.25 (mutt, 7H), 7.18 (d, 2H), 1.37 (s, 9H).

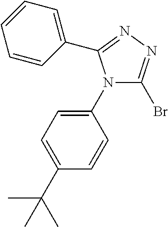 [SMILES: CC(C)(C)c1ccc(-n2c(Br)nnc2-c2ccccc2)cc1]

### Step 3: 3-bromo-4-(4-(tert-butyl)phenyl)-5-phenyl-4H-1,2,4-triazole

A 500 mL round bottom flask equipped with a magnetic stirrer and cooling condenser (set to 10° C.) was charged with 4-(4-(tert-butyl)phenyl)-3-phenyl-4H-1,2,4-triazole (14.6 g, 52.5 mmol), carbon tetrachloride* (125 mL), N-bromosuccinimide (14.0 g, 78.7 mmol), and acetic acid (125 mL). The resulting slurry was heated to reflux resulting in a red solution. The reaction mixture was heated at reflux for 1 h and then cooled to room temperature. The reaction mixture was transferred to a 1 liter flask and 100 mL of methylene chloride and some ice added. A saturated Na₂CO₃ solution was added slowly over the next 3 h until the pH was 7. The mixture was transferred to a 2 liter separatory funnel and separated the lower organic layer. The aqueous layer was extracted 1× with a small amount of methylene chloride which was added to the organics. The organics were washed 1× with saturated NaHCO₃ and 3× with water and dried over Na₂SO₄. After standing overnight, the mixture was filtered and the resulting solution concentrated under vacuum to afford 18 g of crude product as a tan solid. This was triturated with ether to remove some residual bromine. The crude product was dried further in a vacuum oven and then chromatographed in two portions on 340 g silica gel columns using methylene chloride/ethyl acetate as the eluent. Combined yield was 12 g of a white solid (64%). Purity by UPLC was 99.7%. ¹HNMR (CD₂Cl₂) δ 7.54 (d, 2H), 7.45-7.38 (mutt, 3H), 7.32 (t, 2H), 7.18 (d, 2H), 1.38 (s, 9H).

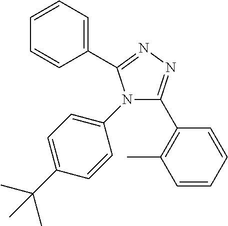 [SMILES: Cc1ccccc1-c1nnc(-c2ccccc2)n1-c1ccc(C(C)(C)C)cc1]

### Step 4: Compound L-1, 4-(4-(tert-butyl)phenyl)-3-phenyl-5-(o-tolyl)-4H-1,2,4-triazole

The reaction was set up in a nitrogen-filled glove box using oven-dried glassware: A 500 mL round bottom flask was charged with Pd₂(dibenzylideneacetone)₃ (3.5 g, 3.8 mmol), 2-Dicyclohexylphosphino-2′,6′-dimethoxybiphenyl (aka SPhos, 6.91 g, 16.8 mmol), and toluene (10 mL). 0-tolyl-boronic acid (6.87 g, 50.5 mmol) and 3-bromo-4-(4-(tert-butyl)phenyl)-5-phenyl-4H-1,2,4-triazole (6.0 g, 16.8 mmol) were then added along with additional toluene (10 mL). Finally, K₃(PO₄) (15.5 g, 67.4 mmol) was added to the reaction mixture. The round bottom flask was taken out of the drybox, and a cooling condenser with a nitrogen inlet on top attached. The reaction mixture was heated to 125° C. and heating continued overnight. The reaction mixture was then cooled to room temperature and vacuum filtered. The filtering column was then washed with approximately 1 liter of ethyl acetate. The combined organics were concentrated under vacuum to afford an orange-red semisolid. Chromatography using ethyl acetate/hexane as the eluent afforded 2.7 g of the desired product (44%). The purity by UPLC was 99.7%. ¹HNMR (CD₂Cl₂) δ 7.47-7.13 (mult, 11H), 6.96 (d, 2H), 2.25 (s, 3H), 1.28 (s, 9H).

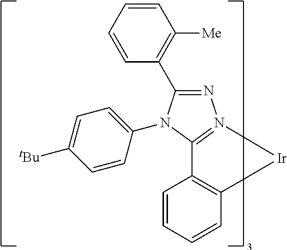

### Step 5: Reaction of Ir(acac)₃ with Compound L1 to Synthesize Compound B1

A 10-mL stainless steel pressure tube was charged with a premixed powder containing 4-(4-(tert-butyl)phenyl)-3-phenyl-5-(o-tolyl)-4H-1,2,4-triazole (1.29 g, 3.51 mmol) and tris(acetylacetonate)iridium (0.34 g, 0.70 mmol). The tube was evacuated and refilled with N₂ to 0 psig three times, and then heated to 250° C. for 3 d. After cooling to room temperature the crude material was removed from the tube by rinsing with methanol followed by dichloromethane. The washes were concentrated under reduced pressure to give 1.55 g of crude product. The product was purified by column chromatography on silica gel using 2% acetone in dichloromethane to give 0.57 g of a yellow solid (63% yield). ¹H NMR (500 MHz, CD₂Cl₂) δ 7.34-7.48 (dd, 2H, ArH), 7.01-7.27 (m, 5H, ArH), 6.79 (t, 1H, ArH), 6.59 (t, 1H, ArH), 6.46 (d, 1H, ArH), 2.08 (s, 3H, ArCH₃), 1.32 (s, 9H, ArC(CH₃)₃). The structure of B1 was confirmed by X-ray diffraction of a single crystal grown from dichloromethane/pentane.

### Synthesis Example 2

This example illustrates the synthesis of Compound L2 and Compound B2.

The compounds were synthesized in two steps from 3-bromo-4-(4-(tert-butyl)phenyl)-5-phenyl-4H-1,2,4-triazole (see step 3 in example 1 above) as follows:

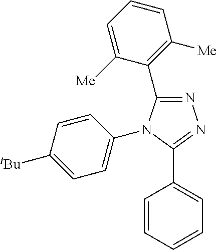 [SMILES: Cc1cccc(C)c1-c1nnc(-c2ccccc2)n1-c1ccc(C(C)(C)C)cc1]

### Step 1: Compound L2, 4-(4-(tert-butyl)phenyl)-3-(2,6-dimethylphenyl)-5-phenyl-4H-1,2,4-triazole

A 500 mL round bottom flask was purged with nitrogen. To this was added water (100 mL), K₂CO₃ (21.3 g, 154 mmol), and 1,2-dimethoxyethane (200 mL). Nitrogen was bubbled into the resulting solution for 20 min. 3-bromo-4-(4-(tert-butyl)phenyl)-5-phenyl-4H-1,2,4-triazole (5.5 g, 15.4 mmol) and 2,6-dimethylbenzeneboronic acid (2.77 g, 18.5 mmol) were then added, and the mixture purged with nitrogen for an additional 15 min. Pd(PPh₃)₄ (0.89 g, 0.77 mmol) was then added and the mixture purged with nitrogen for an additional 6 min. A water cooled condenser was attached and the reaction mixture heated to 145 C. The reaction mixture was heated at reflux for 16 h. TLC at this point showed remaining bromo-triazole so continued heating for an additional 22 h. The reaction at this point was still not complete, so added an additional 150 mg of Pd(PPh₃)₄ and heated for an additional day. TLC at this point showed that the reaction had progressed, but was still not complete. Added an additional 1.9 g (10 mole %) of Pd(PPh₃)₄. The reaction mixture was heated at reflux for an additional 3 h, cooled to room temperature, and then concentrated under vacuum. Methylene chloride was added to the crude product and then washed 2× with water and 2× with brine and dried over Na₂SO₄. The organics were then concentrated to afford a sticky yellow solid. This was chromatographed twice using dichloromethane/ethyl acetate as the eluent to afford 1.84 g (31%) of the desired product as a white solid. ¹HNMR (CD₂Cl₂) δ 7.40-7.10 (mult, 8H), 6.96 (d, 2H), 6.84 (d, 2H), 2.02 (s, 6H), 1.18 (s, 9H).

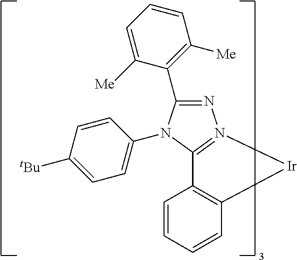

### Step 2: Reaction of Ir(acac)₃ with Compound L2 to Synthesize Compound B2

A 10-mL stainless steel pressure tube was charged with a premixed powder containing 4-(4-(tert-butyl)phenyl)-3-(2,6-dimethylphenyl)-5-phenyl-4H-1,2,4-triazole (1.79 g, 4.69 mmol) and tris(acetylacetonate)iridium (0.46 g, 0.94 mmol). The tube was evacuated and refilled with N₂ to 0 psig three times, and then heated to 250° C. for 3 d. After cooling to room temperature the crude material was removed from the tube by rinsing with dichloromethane. The washes were concentrated under reduced pressure to give 2.27 g of crude product. A suspension of the crude product in dichloromethane was loaded onto a silica gel column. Part of the material eluted onto the column and was not recovered. The yellow insoluble material at the top of the column was removed and recrystallized from toluene to give 0.14 g of yellow crystalline solid (10% yield). ¹H NMR (500 MHz, CD₂Cl₂) δ 7.41 (d, 1H, ArH), 7.29 (d, 1H, ArH), 7.16 (m, 4H, ArH), 7.07 (d, 1H, ArH), 6.94 (t, 2H, ArH), 6.78 (t, 1H, ArH), 6.59 (t, 1H, ArH), 6.42 (d, 1H, ArH), 2.15 (s, 3H, ArCH₃), 1.73 (s, 3H, ArCH₃), 1.30 (s, 9H, ArC(CH₃)₃). The structure of B2 was confirmed by X-ray diffraction of a single crystal grown from dichloromethane/pentane.

### Synthesis Example 3

This example illustrates the synthesis of Compound L3 and Compound B3.

The compounds were synthesized in three steps as follows:

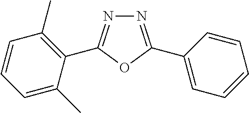 [SMILES: Cc1cccc(C)c1-c1nnc(-c2ccccc2)o1]

### Step 1: 2-(2,6-dimethylphenyl)-5-phenyl-1,3,4-oxadiazole

This compound was synthesized in a one-pot procedure as follows (Reference: Dickson, H. D.; Li, C. Tet. Lett. 2009, 50, 6435): 2,6-dimethylbenzoic acid (5.51 g, 36.7 mmol) was dissolved in anhydrous THF (330 mL) under nitrogen. The solution was stirred under nitrogen and treated with diisopropylethylamine (9.49 g, 12.8 mL, 73.4 mmol), followed by 2-(7-Aza-1H-Benzotriazole-1-yl)-1,1,3,3-tetramethyluronium hexafluorophosphate (aka HATU, 14.0 g, 36.7 mmol) and benzohydrazide (5.00 g, 36.7 mmol). The resulting suspension was heated to reflux and an amber solution eventually formed. The reaction mixture was heated at reflux for a total of 5 days and then cooled to room temperature.

The above mixture was next treated with methyl N-(triethylammoniumsulfonyl)carbamate (aka Burgess Reagent, 15.5 g, 65.0 mmol) which had been prepared separately (see: Khapli, S.; Dey, S.; Mal, D. J. Indian Inst. Sci., July-August 2001, 81, 461.) The mixture was stirred overnight at room temperature. TLC of an aliquot after 18 h showed incomplete reaction, so an additional 150 mmol (4.1 equiv) of Burgess Reagent in anhydrous THF was added. The reaction mixture was again stirred for 18 h under nitrogen. TLC at this point indicated complete reaction. The dark tan-colored reaction mixture was then concentrated to dryness to afford a thick amber-colored syrup. This was suspended in 400 mL of water and extracted 3× with ethyl acetate. The extracts were combined, washed once with 200 mL of water, washed with brine, dried over magnesium sulfate, filtered, and concentrated to dryness to afford an amber oil. This material was divided into portions that were separately purified by chromatography using ethyl acetate/hexane as the eluent. The total yield was 6.77 g of the desired product as a white solid (74%). ¹HNMR (CD₂Cl₂) δ 8.12 (dd, 2H), 7.57 (mult, 3H), 7.37 (t, 1H), 7.22 (d, 2H), 2.39 (s, 6H).

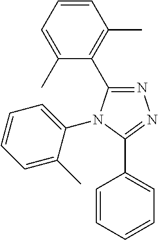 [SMILES: Cc1ccccc1-n1c(-c2ccccc2)nnc1-c1c(C)cccc1C]

### Step 2: Synthesis of Compound L3, 3-(2,6-dimethylphenyl)-5-phenyl-4-(o-tolyl)-4H-1,2,4-triazole. Reference: Chiriac, C. I. et al., Rev. Roum. Chim. 2010, 55, 175

In a nitrogen-filled glovebox, ortho-toluidine (6.65 g, 62.1 mmol) was added to a 250 mL 3-neck round bottom flask equipped with a magnetic stir bar. To this was added anhydrous AlCl₃ (2.07 g, 15.5 mmol) in small portions with stirring to give a light tan-colored solution. The mixture was taken outside the glove box, placed under nitrogen, and heated to 138-140° C. with stirring to afford a light red solution. Heating was maintained for 2 h, during which time the solution color became a deeper red. 2-(2,6-dimethylphenyl)-5-phenyl-1,3,4-oxadiazole (5.75 g, 23.0 mmol) and anhydrous 1-methyl-2-pyrollidinone* (aka NMP, 6.9 mL) were then added. The mixture was heated to reflux (heating block temperature=213° C.) overnight. After 18 h at reflux, the reaction color was dark purple. TLC at this point showed remaining starting material. The mixture was cooled to 60° C. and treated with additional ortho-toluidine (13.3 g, 124 mmol) and AlCl₃ (4.2 g, 31 mmol). The mixture was again heated to reflux. After 5 h at reflux, TLC showed further reaction progress. More ortho-toluidine (6.7 g, 62 mmol) and AlCl₃ (2.1 g, 15.5 mmol) were added and the reaction mixture heated to reflux and stirred overnight. The dark purple mixture was cooled to room temperature, and then stirred with 200 mL aq. HCl while cooled in an ice bath for 1 h. Precipitated solids were filtered off, washed with water, and air dried to afford a solid that was mostly starting oxadiazole. The acidic aqueous filtrate was extracted six times with ethyl acetate. Sodium chloride was added to the aqueous layer and the mixture extracted six more times with ethyl acetate. The extracts were combined and dried over sodium sulfate, filtered, and concentrated to afford 7.04 g of a dark-colored oil. This was chromatographed on a 340 g silica gel column using methylene chloride/ethyl acetate as the eluent. The fractions containing the major product were concentrated to afford the desired product as an off-white solid (2.27 g, 29%). ¹HNMR (CD₂Cl₂) δ 7.5-6.95 (mutt, 12H), 2.28 (s, 3H), 2.0 (s, 3H), 1.81 (s, 3H).

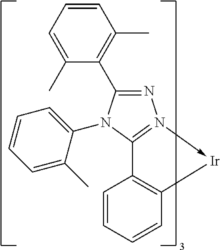

### Step 3: Reaction of Ir(acac)₃ with Compound L3 to Synthesize Compound B3

A 10-mL stainless steel pressure tube was charged with a premixed powder containing 3-(2,6-dimethylphenyl)-5-phenyl-4-(o-tolyl)-4H-1,2,4-triazole (2.00 g, 5.89 mmol) and tris(acetylacetonate)iridium (0.577 g, 1.18 mmol). The tube was evacuated and refilled with N₂ to 0 psig three times, and then heated to 250° C. for 3 d. After cooling to room temperature the crude material was removed from the tube by rinsing with dichloromethane. The washes were concentrated under reduced pressure to give 2.37 g of crude product. The crude product was washed with methanol to remove excess unreacted 3-(2,6-dimethylphenyl)-5-phenyl-4-(o-tolyl)-4H-1,2,4-triazole, and after vacuum drying there was 1.18 g crude product. A 0.3 g portion of the crude product was purified by column chromatography on silica gel, eluting with 2% acetone in dichloromethane to give 0.050 g yellow solid which was further purified by dissolving in refluxing dichloromethane, filtering the solution through a millipore PTFE syringe filter, cooling the solution to room temperature, and precipitating with pentane to give 0.026 g yellow solid. ¹H NMR and UPLC chromatography show that this material contains two isomer in a 90:10 ratio. ¹H NMR (major isomer, 500 MHz, CD₂Cl₂) δ 7.50 (d, 1H, ArH), 7.32 (t, 1H, ArH), 7.25 (d, 1H, ArH), 7.18 (m, 2H, ArH), 7.11 (t, 1H, ArH), 6.97 (d, 1H, ArH), 6.88 (t, 1H, ArH), 6.83 (d, 1H, ArH), 6.58 (t, 1H, ArH), 6.33 (d, 1H, ArH), 2.07 (s, 3H, ArCH₃), 2.05 (s, 3H, ArCH₃), 1.90 (s, 3H, ArCH₃).

### Synthesis Example 4

This example illustrates the synthesis of Compound L10 and Compound B10.

The compounds were synthesized in four convergent steps as follows:

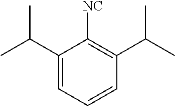

### Step 1: Synthesis of 2-isocyano-1,3-diisopropylbenzene

Reference: Weber, W. P.; Gokel, G. W.; Ugi, I. K. Angew. Chem., Int. Ed. 1972, 11, 530.

A 2-neck, 500-mL round-bottom flask equipped with a stir bar, thermometer, a nitrogen inlet bubbler and a cooling condenser was charged with 2,6-diisopropylaniline (25 g, 141 mmol), benzyltriethylammonium chloride (0.38 g, 1.7 mmol), chloroform (11.3 mL, 141 mmol), and dichloromethane (35 mL). An aqueous 50% sodium hydroxide solution (45 mL) was then added. The solution was rinsed in with water (5 mL). The mixture was stirred at 25° C. for approximately 4 h, then stirred at 43° C. for 24 h. The reaction mixture was then diluted with deionized water (500 mL) and extracted with dichloromethane (2×250 mL). The organic layers were combined and washed with deionized water, followed by brine, separated and dried over K₂CO₃, filtered and concentrated under reduced pressure to give a brown oil (26.9 g). The crude oil was purified by flash column chromatography (4:1 hexanes:dichloromethane) to give a dark brown oil (20 g, 75%). ¹H NMR (500 MHz, CD₂Cl₂) δ 7.35 (m, 1H, p-ArH), 7.19 (m, 2H, m-ArH), 3.38 (m, 2H, ArCH(CH₃)₂), 1.28 (d, 12H, ArCH(CH₃)₂)).

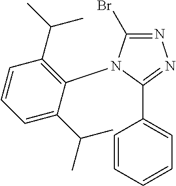 [SMILES: CC(C)c1cccc(C(C)C)c1-n1c(Br)nnc1-c1ccccc1]

### Step 2: Synthesis of 3-bromo-4-(2,6-diisopropylphenyl)-5-phenyl-4H-1,2,4-triazole

Reference: This is a classic Huisgen rearrangement reaction.

An oven-dried 100-mL round-bottom flask equipped with a stir bar, rubber septum and a nitrogen bubbler was charged with 2-isocyano-1,3-diisopropylbenzene (5 g, 27 mmol) and dichloromethane (60 mL). The flask was placed in a water bath at 25° C. and bromine (1.4 mL, 27 mmol) was added dropwise over a period of 2-3 minutes via a plastic syringe. The flask was removed from the water bath, covered with aluminum foil and stirred at 25° C. for 19 h. Another 100-mL round-bottom flask was charged with 5-phenyl-1H-tetrazole (3.95 g, 27 mmol) in dichloromethane (45 mL). Triethylamine (7.5 mL, 54 mmol) was added via a syringe to this suspension, which became homogeneous. This tetrazole solution was transferred to the other round-bottom flask via a cannula over a period of 2 min. The mixture was stirred at 25° C. for 23 h. The mixture was concentrated under reduced pressure to give a brown sludge. The sludge was dissolved in ethyl acetate (300 mL) and washed with water (2×250 mL) then brine, separated, dried over MgSO₄. The resulting imidoyl bromide was purified on a Biotage column chromatography to give 2.2 g of brown oil (20%). This oil was then dissolved in anhydrous toluene and the mixture was refluxed under nitrogen for 1.5 h. The reaction mixture was concentrated under reduced pressure and the crude product was dissolved in a minimal amount of dichloromethane and then passed through a plug of 50 g silica gel by eluting with 1% ethyl acetate in dichloromethane, then 2%, and 5% mixtures to give 1.75 g of an off-white powder (16% overall yield). ¹H NMR (500 MHz, CD₂Cl₂) δ 7.60 (m, 1H, ArH), 7.48 (m, 2H, ArH), 7.37 (m, 3H, ArH), 7.28 (m, 2H, ArH), 2.08 (m, 2H, ArCH(CH₃)₂), 1.20 (d, 6H, ArCH(CH₃)₂), 0.89 (d, 6H, ArCH(CH₃)₂).

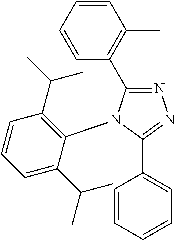 [SMILES: Cc1ccccc1-c1nnc(-c2ccccc2)n1-c1c(C(C)C)cccc1C(C)C]

### Step 3: Synthesis of Compound L10, 4-(2,6-diisopropylphenyl)-3-phenyl-5-(o-tolyl)-4H-1,2,4-triazole

A 2-neck, 100-mL round-bottom flask equipped with a stir bar, condenser, nitrogen bubbler, and a nitrogen sparge tube was charged with K₃PO₄ (1.8 g, 7.8 mmol), o-tolyl boronic acid (0.70 g, 5.2 mmol), toluene (40 mL) and 3-bromo-4-(2,6-diisopropylphenyl)-5-phenyl-4H-1,2,4-triazole (1.0 g, 2.6 mmol). The mixture was sparged with nitrogen for 40 min. In a drybox, a round-bottom flask equipped with a stir bar was charged with tris(benzylideneacetone)dipalladium (0.12 g, 0.13 mmol), 2-dicyclohexylphosphino-2′,6′-dimethoxybiphenyl (0.21 g, 0.52 mmol) and toluene (15 mL). The dark purple solution was stirred for 20 min. This solution was transfer to the reaction mixture via a cannula and the reaction mixture was refluxed under a nitrogen atmosphere for 15.5 h. The reaction mixture was then diluted with a 1:1 ethylacetate:dichloromethane mixture and filtered through a column. The crude product was concentrated under reduced pressure and purified by Biotage column chromatography to give 0.7 g (75%) of a colorless powder. ¹H NMR (500 MHz, CD₂Cl₂) δ 7.60 (m, 1H, ArH), 7.48 (m, 2H, ArH), 7.37 (m, 3H, ArH), 7.28 (m, 2H, ArH), 2.08 (m, 2H, ArCH(CH₃)₂), 1.20 (d, 6H, ArCH(CH₃)₂), 0.89 (d, 6H, ArCH(CH₃)₂).

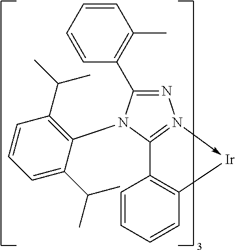

### Step 4: Reaction of Ir(acac)₃ with Compound L10 to synthesize compound B10, fac-Tris{N²-κ-C²-(3-(4-(2,6-diisopropylphenyl)-5-(o-tolyl)-4H-1,2,4-triazolyl)phenyl)iridium

A 10-mL stainless steel pressure tube was charged with a premixed powder containing 4-(2,6-diisopropylphenyl)-3-phenyl-5-(o-tolyl)-4H-1,2,4-triazole (0.69 g, 1.75 mmol) and tris(acetylacetonate)iridium (0.26, 0.53 mmol). The tube was pressured with sparged nitrogen to 0 psig and heated to 250° C. for 3 d during which the pressure reached 170 psig. After cooling to room temperature the crude material was removed from the tube with a spatula and the remaining materials are rinsed with dichloromethane. The materials were concentrated under reduced pressure to give 0.8 g of crude product. Purification was performed by Biotage column chromatography to give 0.360 g of a yellow powder. Further purification was performed on the Biotage to give 0.125 g of a colorless solid (17%) with 99.4% purity by UPLC. ¹H NMR (500 MHz, CD₂Cl₂) δ 7.51 (m, 3H, ArH), 7.26 (m, 6H, ArH), 7.23 (m, 3H, ArH), 7.18 (m, 3H, ArH), 6.89 (m, 3H, ArH), 6.84 (m, 6H, ArH), 6.70 (m, 3H, ArH), 6.5 (m, 3H, ArH), 6.19 (m, 3H, ArH), 2.81 (m, 3H, ArCH(CH₃)₂, 2.31 (s, 12H, ArCH₃, 2.29 (m, 3H, ArCH(CH₃)₂), 0.95 (d, 9H, ArCH(CH₃)₂), 0.81 (d, 9H, ArCH(CH₃)₂), 0.77 (d, 9H, ArCH(CH₃)₂), 0.73 (d, 9H, ArCH(CH₃)₂).

### Synthesis Example 5

This example illustrates the synthesis of Compound L11 and Compound B11.

These compounds were synthesized from 2-(2,6-dimethylphenyl)-5-phenyl-1,3,4-oxadiazole (Synthesis Example 3) as follows:

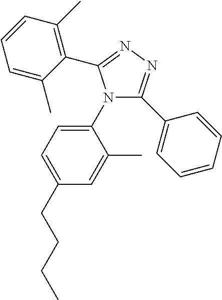 [SMILES: CCCCc1ccc(-n2c(-c3ccccc3)nnc2-c2c(C)cccc2C)c(C)c1]

### Step 1: Synthesis of 4-(4-butyl-2-methylphenyl)-3-(2,6-dimethylphenyl)-5-phenyl-4H-1,2,4-triazole

4-Butyl-2-methylaniline (9.06 g, 55.5 mmol) was added to a 250 ml 3-neck flask containing a stirbar under nitrogen in a glove box. It was stirred and treated with anhydrous AlCl₃ (2.05 g, 15.4 mmol, 0.28 equiv) in small portions with stirring to afford a light tan solution. The mixture was stirred under nitrogen and heated to 138-140° C. to afford a red solution. The mixture was stirred and maintained at 140-142° C. for 2 h. The mixture was kept under nitrogen and treated with 2-(2,6-dimethylphenyl)-5-phenyl-1,3,4-oxadiazole (5.14 g, 20.5 mmol) followed by anhydrous 1-methyl-2-pyrollidinone (6.2 mL). The mixture was then heated at reflux for 20 h. The mixture was cooled to room temperature under nitrogen and treated with another 6.0 grams (37 mmol) of 4-butyl-2-methylaniline followed by another 1.64 grams (12.3 mmol) of anhydrous aluminum chloride. The mixture was stirred at room temperature for 15 min and then heated once more to reflux. The mixture was heated under nitrogen overnight. It was then cooled to room temperature forming a viscous liquid. It was stirred and treated with 200 ml of 10% aqueous HCl and cooled in an ice bath for one hour. The resulting solids were filtered off. The extracts were combined and dried over sodium sulfate, filtered, and concentrated to afford a tan solid. This was chromatographed on a 100 g silica gel column using ethyl acetate/hexane as the eluent. The fractions containing the desired product were concentrated to afford 3.3 g of L11 as a light amber oil 3.28 grams (40% yield). ¹HNMR (CD₂Cl₂) δ 7.47 (d, 2H), 7.38 (t, 1H), 7.32 (t, 2H), 7.24 (t, 1H), 7.12 (d, 1H), 7.0-6.90 (mult, 4H), 2.58 (mult, 2H), 2.22 (s, 3H), 2.01 (s, 3H), 1.79 (s, 3H), 1.57 (mult, 2H), 1.33 (mult, 2H), 0.91 (t, 3H).

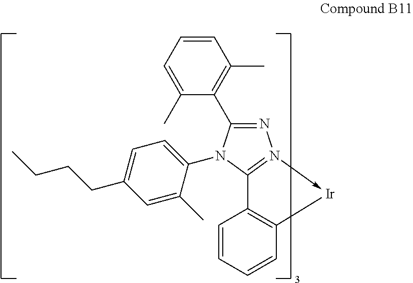

### Step 2: Reaction of Ir(acac)₃ with Compound L11 to Synthesize Compound B11

4-(4-butyl-2-methylphenyl)-3-(2,6-dimethylphenyl)-5-phenyl-4H-1,2,4-triazole (3.25 g, 8.22 mmol) and Ir(acac)₃ (0.805 g, 1.64 mmol) were combined in a 10 mL stainless steel shaker tube. The tube was evacuated and then purged with nitrogen. The tube and its contents were then heated to 250° C. and the temperature maintained for 72 h. After 72 h, the tube was cooled to ambient temperature and vented. The contents were rinsed out with 500 mL of ethyl acetate into a round bottom flask. The resulting dark brown solution was concentrated to dryness, affording 2.3 g of a viscous, dark brown oil. The dark brown oil was chromatographed on a 340 g silica gel column using a gradient of 6 to 50% ethyl acetate in hexane. Three major fractions, corresponding to different diastereomers, were eluted. The first fraction to elute was collected and concentrated to dryness. Recrystallization from ethyl acetate afforded 70 mg of a yellow crystalline solid. ¹H NMR (CD₂Cl₂) δ 7.50 (d, 1H), 7.15-7.05 (mult, 3H), 6.97 (mult, 2H), 6.86 (mult, 2H), 6.59 (t, 1H), 6.32 (d, 1H), 2.59 (mult, 2H), 2.04 (s, 3H), 2.02 (s, 3H), 1.90 (s, 3H), 1.58 (mult, 2H), 1.35 (mult, 2H), 0.92 (t, 3H). In addition, resonances corresponding to ˜0.50 equiv of EtOAc were observed in this sample. Consistent with the ¹H NMR data, this compound was shown by x-ray crystallography to be the fac-RRR/SSS isomer of compound B11. This material is used in the device example below. The other diastereomers of compound B11 were also isolated in later chromatography fractions.

### Synthesis Example 6

This example illustrates the synthesis of Compound L12 and Compound B12.

These compounds were synthesized from 3-bromo-4-(2,6-diisopropylphenyl)-5-phenyl-4H-1,2,4-triazole (Synthesis Example 4) as follows:

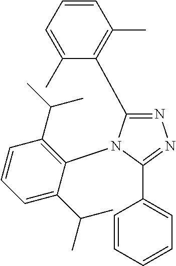 [SMILES: Cc1cccc(C)c1-c1nnc(-c2ccccc2)n1-c1c(C(C)C)cccc1C(C)C]

### Step 1: Synthesis of Compound L12, 4-(2,6-diisopropylphenyl)-3-phenyl-5-(2,6-dimethylphenyl)-4H-1,2,4-triazole

A 2-neck, 100-mL round-bottom flask equipped with a stir bar, condenser, nitrogen bubbler, and a nitrogen sparge tube was charged with K₃PO₄ (1.8 g, 7.8 mmol), 2,6-dimethyl phenylboronic acid (0.70 g, 5.2 mmol), toluene (40 mL) and 3-bromo-4-(2,6-diisopropylphenyl)-5-phenyl-4H-1,2,4-triazole (1.0 g, 2.6 mmol). The mixture was sparged with nitrogen for 40 min. In a drybox, a round-bottom flask equipped with a stir bar was charged with tris(benzylideneacetone)dipalladium (0.12 g, 0.13 mmol), 2-dicyclohexylphosphino-2′,6′-dimethoxybiphenyl (0.21 g, 0.52 mmol) and toluene (15 mL). The dark purple solution was stirred for 20 min. This solution was transfer to the reaction mixture via a cannula and the reaction mixture was refluxed under a nitrogen atmosphere for 15.5 h. The reaction mixture was then diluted with a 1:1 ethylacetate:dichloromethane mixture and filtered through a column. The crude product was concentrated under reduced pressure and purified by Biotage column chromatography to give of a colorless powder. ¹H NMR (500 MHz, CD₂Cl₂) δ 7.60 (m, 1H, ArH), 7.48 (m, 2H, ArH), 7.37 (m, 3H, ArH), 7.28 (m, 2H, ArH), 2.67 (s, 6H, Ar(CH₃)₂, 2.08 (m, 2H, ArCH(CH₃)₂), 1.20 (d, 6H, ArCH(CH₃)₂), 0.89 (d, 6H, ArCH(CH₃)₂).

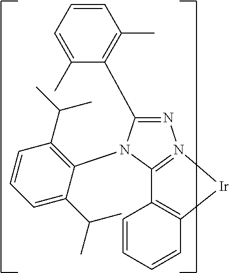

### Step 2: Reaction of Ir(acac)₃ with Compound L12 to synthesize compound B12, fac-Tris{N²-κ-C²-(3-(4-(2,6-diisopropylphenyl)-5-(2,6-dimethylphenyl)-4H-1,2,4-triazolyl)phenyl)iridium

A 10-mL stainless steel pressure tube was charged with a premixed powder containing 4-(2,6-diisopropylphenyl)-3-phenyl-5-(2,6-dimethylphenyl)-4H-1,2,4-triazole (0.77 g, 1.90 mmol) and tris(acetylacetonate)iridium (0.27, 0.55 mmol). The tube was pressured with sparged nitrogen to 0 psig and heated to 250° C. for 3 d during which the pressure reached 170 psig. After cooling to room temperature the crude material was removed from the tube with a spatula and the remaining materials are rinsed with dichloromethane. The materials were concentrated under reduced pressure to give 0.85 g of crude product. Purification was performed by Biotage column chromatography to give 0.575 g of a yellow powder. Further purification was performed on the Biotage to give 0.385 g of a yellow solid (49%). ¹H NMR (500 MHz, CD₂Cl₂) δ 7.48 (m, 3H, ArH), 7.23 (m, 6H, ArH), 7.11 (m, 3H, ArH), 6.95 (m, 3H, ArH), 6.88 (m, 3H, ArH), 6.79 (m, 3H, ArH), 6.66 (m, 3H, ArH), 6.49 (m, 3H, ArH), 6.17 (m, 3H, ArH), 2.78 (m, 3H, ArCH(CH₃)₂), 2.31 (m, 3H, ArCH(CH₃)₂), 2.14 (s, 9H, Ar(CH₃)₂), 1.58 (s, 9H, Ar(CH₃)₂), 0.93 (d, 9H, ArCH(CH₃)₂), 0.87 (d, 9H, ArCH(CH₃)₂), 0.76 (d, 9H, ArCH(CH₃)₂), 0.66 (d, 9H, ArCH(CH₃)₂).

### Device Examples

These examples demonstrate the fabrication and performance of OLED devices.

(1) Materials
HIJ-1 is an electrically conductive polymer doped with a polymeric fluorinated sulfonic acid. Such materials have been described in, for example, published U.S. patent applications US 2004/0102577, US 2004/0127637, US 2005/0205860, and published PCT application WO 2009/018009.
HT-1 is a triarylamine-containing polymer. Such materials have been described in, for example, published PCT application WO 2009/067419.

Host-1 is a indolocarbazole derivative, usually used as green host. Host-2 is the carbazole-thiophene derivative shown below

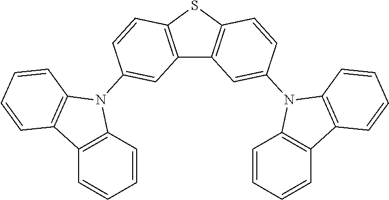 [SMILES: c1ccc2c(c1)c1ccccc1n2-c1ccc2sc3ccc(-n4c5ccccc5c5ccccc54)cc3c2c1]

ET-1 is a metal quinolate complex.

Comparative compound A1 is shown below.

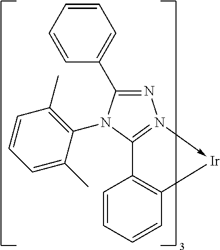

The devices had the following structure on a glass substrate:
anode=Indium Tin Oxide (ITO), 50 nm
hole injection layer=HIJ-1 (50 nm)
hole transport layer=HT-1 (20 nm)
photoactive layer, discussed below=100:14 Host:dopant ratio (43 nm);
anti-quenching layer=Host-1 or Host-2 (10 nm)
electron transport layer=ET-1 (10 nm)
electron injection layer/cathode=CsF/Al ( 1/100 nm)

(2) Device Fabrication

OLED devices were fabricated by a combination of solution processing and thermal evaporation techniques. Patterned indium tin oxide (ITO) coated glass substrates from Thin Film Devices, Inc were used. These ITO substrates are based on Corning 1737 glass coated with ITO having a sheet resistance of 30 ohms/square and 80% light transmission. The patterned ITO substrates were cleaned ultrasonically in aqueous detergent solution and rinsed with distilled water. The patterned ITO was subsequently cleaned ultrasonically in acetone, rinsed with isopropanol, and dried in a stream of nitrogen.

Immediately before device fabrication the cleaned, patterned ITO substrates were treated with UV ozone for 10 minutes. Immediately after cooling, an aqueous dispersion of HIJ-1 was spin-coated over the ITO surface and heated to remove solvent. After cooling, the substrates were then spin-coated with a hole transport solution, and then heated to remove solvent. The substrates were masked and placed in a vacuum chamber. The photoactive layer, the electron transport layer and the anti-quenching layer were deposited by thermal evaporation, followed by a layer of CsF. Masks were then changed in vacuo and a layer of Al was deposited by thermal evaporation. The chamber was vented, and the devices were encapsulated using a glass lid, desiccant, and UV curable epoxy.

(3) Device Characterization

The OLED samples were characterized by measuring their (1) current-voltage (I-V) curves, (2) electroluminescence radiance versus voltage, and (3) electroluminescence spectra versus voltage. All three measurements were performed at the same time and controlled by a computer. The current efficiency of the device at a certain voltage is determined by dividing the electroluminescence radiance of the LED by the current density needed to run the device. The unit is a cd/A. The color coordinates were determined using either a Minolta CS-100 meter or a Photoresearch PR-705 meter.

### Examples 1-4 and Comparative Example A1

These examples illustrate the use of compounds having Formula II as the light emitting material in a device.

The materials used and the results are given in Table 1 below.

TABLE I
Device results

| | | | | | EQE @ | Voltage @ 20 | T70 @ |
|---|---|---|---|---|---|---|---|
| | | | EL peak | | 1000 nits | mA/cm2 | 1000 nits |
| Example | Dopant | Host | (nm) | CIE (x, y) | (%) | (V) | (hours) |
| Comparative A1 | compound A1 | Host-1 | 530 | (0.36, 0.565) | 6.6 | 10 | 1.8* |
| 1 | Compound B1 | Host-2 | 484 | (0.206, 0.44) | 20 | 9.6 | 230 |
| 2 | Compound B2 | Host-2 | 483 | (0.2 0.431) | 23.9 | 9.2 | 160 |
| 3 | Compound B3 | Host-2 | 473 | (0.18, 0.359) | 19 | 8.2 | ** |
| 4 | Compound B10 | Host-2 | 476 | (0.178, 0.369) | 17.8 | 9.2 | 460 |
| 5 | Compound B11 | Host-2 | 473 | (0.183, 0.378) | 17.1 | 9.3 | 45 |

All data @ 1000 nits.
E.Q.E. is the external quantum efficiency;
CIE(x, y) are the x and y color coordinates according to the C.I.E. chromaticity scale (Commission Internationale de L'Eclairage, 1931);
T70 is a measure of lifetime and is the time to reach 70% of initial luminance.
*extrapolated from 4000 nits
**Device of Example 3 shorted during lifetesting.

It can be seen from Table I, that the compounds of the invention provided significantly better device performance. The compound in comparative example A1 gave green electroluminescence, and therefore was evaluated with a typical green host, Host-1. Not only is the color not blue, the efficiency and lifetime are also low.

In comparative compound A1 of Comparative Example A1, the phenyl group connected to the carbon atom of the triazole ring does not have any substituent at the ortho position. By adding methyl substituent group at the ortho position as in Examples 1 and 2, the electroluminescence color is substantially blue-shifted, the efficiency enhanced, and the lifetime lengthened.

In Examples 1 and 2, the phenyl group connected to the nitrogen atom of the triazole ring does not have any substituent at the ortho position. By adding an alkyl substituent group at the ortho position as in Examples 3 and 4, the electroluminescence color is further blue-shifted, while the high efficiency and long lifetime are maintained.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

What is claimed is:

1. A compound having Formula II 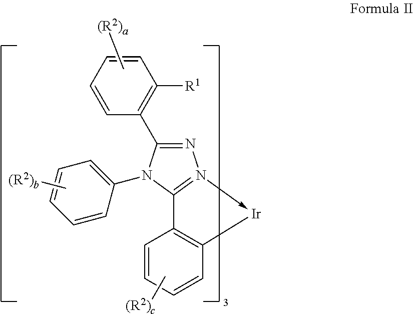
wherein:
R¹ is selected from the group consisting of alkyl having 1-6 carbons, silyl having 3-6 carbons, and deuterated analogs thereof;
R² is the same or different at each occurrence and is selected from the group consisting of alkyl, silyl, aryl, and deuterated analogs thereof;
a and c are the same or different and are an integer from 0-5; and
b is an integer from 0-5.

2. The compound of claim 1, wherein the compound is at least 10% deuterated.

3. The compound of claim 1, wherein R¹ is an alkyl or deuterated alkyl having 1-6 carbons.

4. The compound of claim 1, wherein R¹ is an alkyl or deuterated alkyl having 1-3 carbons.

5. The compound of claim 1, wherein a>0 and R² is meta to R¹.

6. The compound of claim 1, wherein a>0 and R² is an alkyl or deuterated alkyl having 1-6 carbons.

7. The compound of claim 1, wherein b>0 and R² is an alkyl or deuterated alkyl having 1-6 carbons.

8. The compound of claim 1, wherein b>0 and R² is a hydrocarbon aryl or deuterated hydrocarbon aryl having 6-12 ring carbons.

9. The compound of claim 1, wherein b>0 and R² is an alkylaryl or deuterated alkylaryl having 6-20 carbons.

10. The compound of claim 1, wherein c>0 and R² is an alkyl or deuterated alkyl having 1-6 carbons.

11. The compound of claim 1, wherein c>0 and R² is a hydrocarbon aryl or deuterated hydrocarbon aryl having 6-12 ring carbons.

12. The compound of claim 1, wherein c>0 and R² is an alkylaryl or deuterated alkylaryl having 6-20 carbons.

13. A compound selected from compound B1 through B12.

14. An organic electronic device comprising a first electrical contact, a second electrical contact and a photoactive layer therebetween, the photoactive layer comprising a compound having Formula II 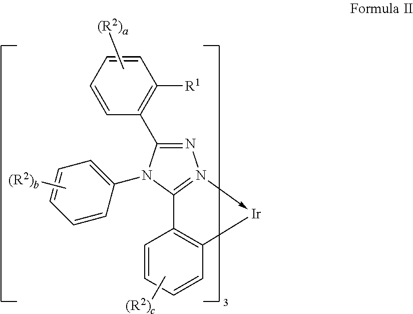
wherein:
R¹ is selected from the group consisting of alkyl having 1-6 carbons, silyl having 3-6 carbons, and deuterated analogs thereof;
R² is the same or different at each occurrence and is selected from the group consisting of alkyl, silyl, aryl, and deuterated analogs thereof;
a and c are the same or different and are an integer from 0-5; and
b is an integer from 0-5.

15. The device of claim 14, wherein the photoactive layer comprises the electroactive compound of Formula II and further comprises a host material.

16. The device of claim 14, wherein the photoactive layer consists essentially of the electroactive compound of Formula II and a host material.

17. A compound having Formula I 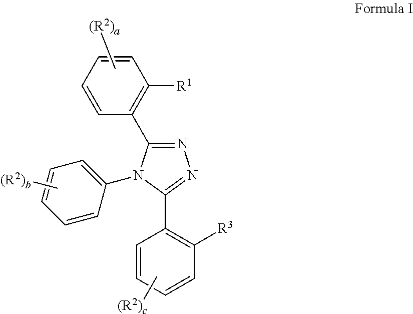
wherein:
R¹ is selected from the group consisting of alkyl having 1-6 carbons, silyl having 3-6 carbons, and deuterated analogs thereof;
R² is the same or different at each occurrence and is selected from the group consisting of alkyl, silyl, aryl, and deuterated analogs thereof;
R³ is H or D;
a and c are the same or different and are an integer from 0-5; and
b is an integer from 0-5.
